(19) United States
(12) Patent Application Publication
(10) Pub. No.: US 2025/0126919 A1
(43) Pub. Date: Apr. 17, 2025

(54) IMAGING DEVICE FOR ACQUIRING A VISIBLE IMAGE AND AN INFRARED IMAGE

(71) Applicant: COMMISSARIAT A L'ENERGIE ATOMIQUE ET AUX ENERGIES ALTERNATIVES, Paris (FR)

(72) Inventor: Sébastien BECKER, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/909,097

(22) Filed: Oct. 8, 2024

(30) Foreign Application Priority Data
Oct. 16, 2023 (FR) 2311081

(51) Int. Cl. H01L 27/146

(52) U.S. Cl. CPC H10F 39/809; H10F 39/018; H10F 39/182; H10F 39/184; H10F 39/811

(57) ABSTRACT

An imaging device for acquiring visible and infrared images, including a visible matrix sensor, and infrared matrix sensor, and a readout integrated circuit superimposed on the visible matrix sensor and on the infrared matrix sensor and formed by a readout stack including electronic elements and an interconnection stack. The readout stack is located between the sensitive layers of the matrix sensors, and the interconnection stack is located on the rear face of the infrared matrix sensor. In addition, conductive vias electrically connect respectively the interconnection stack to electronic elements of the visible matrix sensor, to electronic elements of the readout stack, and to electronic elements of the infrared matrix sensor.

### TECHNICAL FIELD

The field of the invention is that of imaging devices adapted to acquire a visible image and an infrared image of the same scene. Imaging devices of this type make it possible in particular to reconstitute, in addition to a visible image of the scene (in grey levels or in colours), depth information on this same scene.

### PRIOR ART

Imaging devices exist that make it possible to acquire, simultaneously or successively, a visible image and an infrared image of one and the same scene. The visible image corresponds to a two-dimensional image of the scene, which can be in grey levels or in RGB (Red Green Blue) colours, whereas the infrared image can make it possible to reconstitute a depth map of the scene. For this purpose, the imaging devices include a visible matrix sensor and an infrared matrix sensor, which can be superimposed one on the other, so that they have substantially the same optical alignment and make it possible to reduce the overall dimensions. The visible and infrared matrix sensors can then be integrated monolithically on a readout substrate that includes a readout integrated circuit of the CMOS type.

Thus documents EP 3 503 192 A1 and US 2021/305206 A1 describe examples of such an imaging device where the visible matrix sensor and the infrared matrix sensor are superimposed one on the other while being assembled on a readout substrate.

In these examples, the visible matrix sensor includes a sensitive layer where visible detection pixels are formed, as well as an interconnection stack electrically connected to electronic elements (transistors, diodes, etc) of the visible detection pixels. Likewise, the infrared matrix sensor includes a sensitive layer where infrared detection pixels are formed, as well as an interconnection stack electrically connected to the photodiodes of the infrared detection pixels. The whole of the infrared matrix sensor is located on the rear face of the visible matrix sensor. Finally, the readout substrate includes a readout integrated circuit of the CMOS type, assembled on the rear face of the infrared matrix sensor.

However, there is a need to improve certain aspects of such imaging devices, whether with regard to the structural configuration and/or the manufacturing method.

### DESCRIPTION OF THE INVENTION

The objective of the invention is to at least partly remedy the drawbacks of the prior art, and for this purpose to propose an imaging device adapted to acquire a visible image and an infrared image, including:
a visible matrix sensor, including a first sensitive layer in which visible detection pixels including at least one electronic element are defined;
an infrared matrix sensor, including a second sensitive layer, superimposed on the first sensitive layer, in which infrared detection pixels including at least one electronic element are defined;
a readout integrated circuit, superimposed on the visible matrix sensor and on the infrared matrix sensor, formed by a readout stack including electronic elements and an interconnection stack.

According to the invention, the readout stack is located between the first sensitive layer and the second sensitive layer, and the interconnection stack is located on the rear face of the infrared matrix sensor.

In addition, conductive vias electrically connect respectively the interconnection stack to the electronic elements of the visible matrix sensor, to the electronic elements of the readout stack, and to the electronic elements of the infrared matrix sensor.

Certain preferred but non-limitative aspects of this imaging device are as follows.

The visible matrix sensor can include a first insulating layer located under the first sensitive layer, and the readout stack can include a second insulating layer located above the electronic elements of the readout stack, the first insulating layer and the second insulating layer being in contact with each other.

The readout stack can include a third insulating layer located under the electronic elements of the readout stack, and the infrared matrix sensor can include a fourth insulating layer located above the second sensitive layer, the third insulating layer and the fourth insulating layer being in contact with each other.

Conductive vias can extend directly from the electronic elements of the infrared matrix sensor as far as conductive portions of the interconnection stack.

Conductive vias can extend directly from the electronic elements of the readout stack as far as conductive portions of the interconnection stack.

Conductive vias can extend directly from the electronic elements of the visible matrix sensor as far as conductive portions of the interconnection stack.

Conductive vias can extend directly from conductive portions of the readout stack, which are in electrical contact with the electronic elements of the visible matrix sensor, as far as conductive portions of the interconnection stack.

The second sensitive layer can be a structured layer in a plane parallel to the plane of the infrared matrix sensor forming a plurality of portions of second sensitive layer, distinct from each other in the parallel plane, so that the conductive vias electrically connecting, respectively, the interconnection stack firstly to the electronic elements of the visible matrix sensor and secondly to the electronic elements of the readout stack, do not pass through the second sensitive layer.

The second sensitive layer can be a structured layer in a plane parallel to the plane of the infrared matrix sensor forming a plurality of portions of second sensitive layer connected in pairs by a connecting portion of lesser thickness, so that the conductive vias electrically connecting, respectively, the interconnection stack firstly to the electronic elements of the visible matrix sensor and secondly to the electronic elements of the readout stack, pass through the connecting portions.

The readout stack and the interconnection stack can be first readout and interconnection stacks of a first readout integrated circuit, and a second readout integrated circuit, formed by second readout and interconnection stacks, can be assembled on the first readout integrated circuit, the second interconnection stack being assembled and connected to the rear face of the first interconnection stack.

The imaging device can include a reflective layer, located between the infrared matrix sensor and the interconnection stack, adapted to reflect incident infrared radiation intended to be detected by the infrared matrix sensor.

The reflective layer can form, with the infrared matrix sensor, the readout stack and an insulating layer located between the first sensitive layer and the readout stack, an optical cavity resonant at the wavelength of the infrared radiation.

The invention also relates to a method for manufacturing an imaging device according to any one of the preceding features, including the following steps:
producing the visible matrix sensor, a first insulating layer covering the first sensitive layer where the electronic elements lie flush;
producing a first structure intended to form the readout stack, including a second insulating layer, by molecular bonding of the second insulating layer on the first insulating layer, and then producing the readout stack;
producing a second structure intended to form the infrared matrix sensor, including a fourth insulating layer, by molecular bonding of the fourth insulating layer on a third insulating layer of the readout stack, and then producing the infrared matrix sensor;
producing the interconnection stack as from the rear face of the infrared matrix sensor.

During the step of producing the electronic elements of the readout stack, a temperature rise to a temperature of at least 1000° C. can be implemented.

The step of producing the electronic elements of the infrared matrix sensor can be implemented after the step of producing the electronic elements of the readout stack.

### BRIEF DESCRIPTION OF THE DRAWINGS

Other aspects, aims, advantages and features of the invention will become more apparent upon reading the following detailed description of preferred embodiments thereof, given as a non-limiting example, and made with reference to the appended drawings, wherein:

FIG. 1 is a schematic partial view, in cross section, of an imaging device according to one embodiment;

FIGS. 2A to 2H illustrate various steps of a method for manufacturing an imaging device identical or similar to the one in FIG. 1;

FIG. 3A is a schematic partial view, in cross section, of an imaging device according to a variant embodiment;

FIG. 3B is a schematic partial view, in cross section, of an imaging device according to a variant embodiment similar to the one in FIG. 3A;

FIG. 4 is a schematic partial view, in cross section, of an imaging device according to a variant embodiment;

FIG. 5 is a schematic partial view, in cross section, of an imaging device according to a variant embodiment.

### DETAILED DESCRIPTION OF PARTICULAR EMBODIMENTS

In the figures and in the remainder of the description, the same references represent identical or similar elements. In addition, the various elements are not shown to scale so as to promote clarity of the figures. Moreover, the different embodiments and variants are not mutually exclusive and can be combined together. Unless indicated otherwise, the terms “substantially”, “about”, “of the order of” mean within a 10% margin, and preferably within a 5% margin. Moreover, the terms “included between . . . and . . . ” and the like mean that the bounds are included, unless stated otherwise.

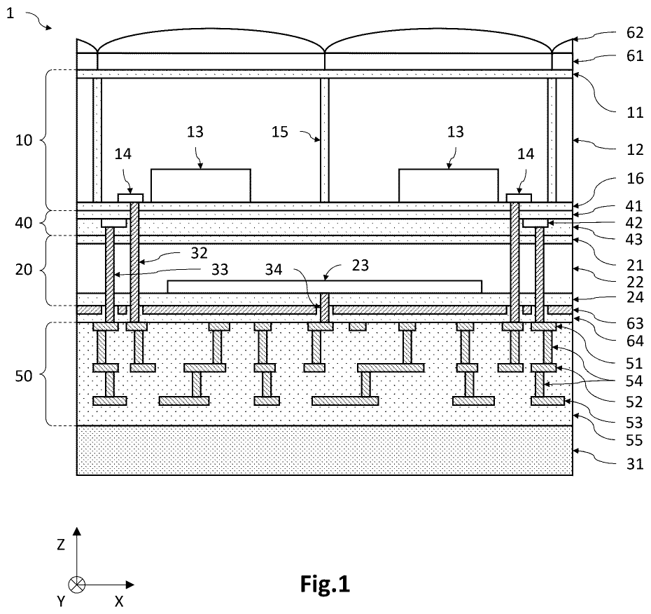

FIG. 1 is a schematic partial view, in cross section, of an imaging device 1 according to one embodiment. It is adapted to acquire a visible image and an infrared image of one and the same scene, simultaneously or sequentially. In this example, one and the same infrared detection pixel extends facing a plurality of adjacent visible detection pixels. In a variant, one and the same infrared detection pixel may extend facing only one visible detection pixel. 10

An orthogonal three-dimensional direct reference frame XYZ is defined here and for the remainder of the description, where the plane XY is substantially parallel to the principal plane of a support substrate 31, and where the axis Z is oriented in the direction of the matrix sensors 10, 20. In the remainder of the description, the terms “lower” and “upper” should be understood as relating to an increasing positioning when moving away from the support substrate 31 in the direction +Z. Moreover, the terms “front face” and “rear face” of an element or of a layer designate respectively the face oriented towards the scene to be imaged (from where the light beams of the visible and infrared images to be acquired come) and the face opposite to the scene.

In general terms, the imaging device 1 includes a vertical superimposition (along the Z axis) of a visible matrix sensor 10 for acquiring the visible image, of an infrared matrix sensor 20 for acquiring the infrared image, and of a readout integrated circuit 40, 50 of the CMOS type electrically connected to the visible 10 and infrared 20 matrix sensors. These three elements are assembled with each other monolithically.

As described in detail below, the readout integrated circuit 40, 50 is formed by a readout stack 40 and an interconnection stack 50. The readout stack 40 is located between a sensitive layer 12 of the visible matrix sensor 10 and a sensitive layer 22 of the infrared matrix sensor 20. On the other hand, the interconnection stack 50 is located on the rear face of the infrared matrix sensor 20, here between the latter and a support substrate 31. Conductive vias 32 provide an electrical connection, direct or indirect, between the electronic elements 14 of the visible matrix sensor 10 and the interconnection stack 50; the conductive vias 34 provide the electrical connection between the electronic elements 23 between of the infrared matrix sensor 20 and the interconnection stack 50; and the conductive vias 33 provide an electrical connection between the electronic elements 42 of the readout stack 40 and the interconnection stack 50.

Electronic elements of the visible 10 and infrared 20 matrix sensors means here a doped portion of a semiconductor layer that has or participates in a function of collecting or storing photogenerated electrical charges. It may thus be a case, among other things, of a doped portion for connecting minority charge carriers of a photodetector such as a photodiode; of a doped portion for temporary storage of photogenerated charges coming from a photodiode, such as a readout node (Sensing or Floating Diffusion Node); or of a doped portion of a transfer transistor (Transfer Gate) that transfers the photogenerated charges from the photodiode to the readout node.

Electronic element of the readout stack 40 means here a doped portion of a semiconductor layer that participates in the processing of electrical information coming from the visible 10 and infrared 20 matrix sensors. It may thus be a case, among other things, of a doped portion of a diode or of a transistor, among others.

The visible matrix sensor 10 is adapted to acquire a visible image of the scene. It includes for this purpose a plurality of detection pixels each adapted to receive and detect the visible light radiation, these detection pixels being formed in a sensitive layer 12 adapted to absorb the visible light radiation to be detected.

The sensitive layer 12 is produced from a semiconductor material, preferably doped, which is selected to absorb the visible light radiation of interest. By way of example, the sensitive layer 12 may be made from monocrystalline silicon. It may have a thickness of between 2 and 10 μm, for example of the order of 4 μm. The sensitive layer 12 is formed here by a layer made from the same material in terms of chemical elements, but may be formed by a stack of sublayers made from different materials.

Each visible detection pixel corresponds to a part of the sensitive layer 12 in the plane XY, and includes a photodiode 13 as well as at least one electronic element 14, for example a readout node (sensing node or floating diffusion node) that receives the photogenerated charges transmitted by a transfer transistor (transfer gate, not shown on the figures). Such a readout node 14 acts as a temporary charge accumulator. The transfer transistor makes it possible to activate the transfer of the photogenerated charge carriers from the photodiode 13 to the readout node 14. The photodiode 13 and the readout node 14 are located in the sensitive layer 12 and lie flush with the rear face thereof. The transfer transistor can be located in the lower insulating layer 16 and also lie flush with the rear face of the sensitive layer 12. It is in electrical contact with the photodiode 13 and the readout node 14.

The detection pixels are separated from one another, in the plane XY, by isolation structures 15 that extend vertically through the sensitive layer 12, preferably over the entire thickness thereof.

These isolation structures 15 can be deep isolation trenches of the DTI type (standing for Deep Trench Isolation) produced entirely from an electrically insulating material. They can also be capacitive deep isolation trenches (CDTI, standing for Capacitive Deep Trench Isolation), and be formed from a core made from an electrically conductive material, for example doped polycrystalline silicon, surrounded by a sheath made from an electrically insulating material, for example a silicon oxide. These structures 15 of the CDTI type can then be electrically connected to the readout circuit and provide an optical isolation of the detection pixels visible to each other, and make it possible to prevent the diffusion of the photogenerated charge carriers from one visible detection pixel to another.

An upper isolating layer 11 extends here over and in contact with the front face of the sensitive layer 12. This isolating layer is produced from an electrically insulating material such as a silicon oxide or a silicon nitride for example. It can entirely cover the sensitive layer 12. One or more layers can also be present, which fulfil optical functions such as a non-reflection function.

The imaging device 1 can include an optical structure having one or more optical functions, for example here filtering and focusing. Thus, in this example, each visible detection pixel is provided with a colour filter 61, different from one pixel to another, so that the visible image acquired by the visible matrix sensor 10 is a colour image, for example of the RGB type. The colour filters 61 can be coloured-resin filters, and are located above the corresponding parts of the sensitive layer 12. They are adapted to filter the wavelengths outside the visible spectral range of interest, while here transmitting the wavelengths in the infrared. Naturally, the colour filters 61 may be absent, the visible image then being a grey-level monochromatic image. Moreover, each visible detection pixel is here provided with a microlens 62, located above the colour filters 61 where applicable. The microlenses 62 are adapted to focus the incident radiation in the direction of the photodiode 13.

The infrared matrix sensor 20 is adapted to acquire an infrared image of the scene. It includes for this purpose a plurality of detection pixels each adapted to receive and detect the infrared light radiation, these detection pixels being formed in a sensitive layer 22, continuous or not in the plane XY, adapted to absorb the infrared light radiation.

The sensitive layer 22 is for example produced from a semiconductor material, preferably doped, making it possible to absorb the infrared light radiation of interest. The sensitive layer 22 can obviously be formed from a stack of sublayers. By way of example, the sensitive layer 22 is produced from an element or a semiconductor compound in group IV (column IV of the periodic table), for example from germanium or from a silicon and germanium (SiGe) compound, or from an III-V compound, for example from InGaAs, from InGaAsP or others. It may also be a case of semiconductor materials based on quantum boxes (also called quantum film or quantum dots) or from quantum multi-well (QWIP) materials, or of the superlattice type. It may have a thickness that depends on the centre wavelength of the infrared spectral range, for example a thickness of between 50 nm and 10 μm.

Each infrared detection pixel corresponds to a part of the sensitive layer 22 in the plane XY, and includes at least one photodetector 23 for photogeneration of charge carriers, such as, for example, a photodiode (as shown on FIG. 1). In this example, each photodiode 23 is directly connected to the integrated readout circuit 40, 50. However, electronic elements such as transistors may also be present between the photodiode 23 and the readout circuit 40, 50. The photodiode 23 is located in the sensitive layer 22 and lies flush with the rear face thereof. In this example, the electronic element 23 of the infrared detection pixel corresponds to the photodiode, but it could also be a case of an electronic charge-extraction element (transfer transistor, readout node, etc).

In this example, the infrared detection pixels are located facing (perpendicularly) the visible detection pixels. The dimensions of the infrared detection pixels in the plane XY are here greater than those of the visible detection pixels, but in a variant they could be of the same order. Here, each infrared detection pixel extends facing 2×2 visible detection pixels, while being aligned on the centre of the surface formed by the 2×2 visible detection pixels.

Moreover, at least one upper insulating layer 21, produced from an electrically insulating material, covers the sensitive layer 22 and has a planar front face. It is a case of a bonding layer used to provide the molecular bonding of the infrared matrix sensor to the rear face of the readout stack 40. Moreover, at least one lower insulating layer 24, produced from an electrically insulating material, extends under the sensitive layer 22 and preferentially has a planar rear face.

Moreover, the imaging device 1 preferably includes a reflective layer 63 that extends in the plane XY under the visible detection pixels and the infrared detection pixels, to provide reflection of the incident light radiation to be detected. It can be produced from a metal material, for example Ti, Al, Cu and alloys thereof, or from highly doped silicon, for example of the order of 10²⁰ cm⁻³. It can have a thickness of the order of 400 nm when it is produced from silicon. It can also be a case of a multilayer dielectric stack of the Bragg mirror type.

It should be noted that the infrared matrix sensor 20 may be of the resonant cavity type, as described in particular in the patent application FR 3 130 450 A1. Thus the sensitive layer 22 may be a layer of low thickness, for example of the order of 500 nm or even less. The sensitive layer 22 is located in a resonant optical cavity delimited vertically by the reflective layer 63 and an assembly formed by the lower bonding insulating layer 16, the readout stack 40 and the upper bonding insulating layer 21. This assembly preferably has a thickness of the order of a few hundreds of nanometres. The insulating layers of this assembly are preferably produced from a silicon oxide. Such a configuration makes it possible to obtain an infrared radiation absorption greater than 80% in the sensitive layer 22.

The readout integrated circuit (ROIC) 40, 50 includes a readout stack 40 and an interconnection stack 50, here superimposed along the Z axis and spaced apart from each other.

The readout stack 40 is a stack of the FEOL type (standing for Front End Of Line). It is formed by layers based on semiconductor, where electronic elements 42 (diodes, transistors, etc) and optionally passive elements (capacitors, resistors, etc) are implemented. The electronic elements are connected to the electronic elements of the detection pixels of the visible 10 and infrared 20 matrix sensors on the one hand, and to at least one external connection pad (not shown) on the other hand, the latter being intended to connect the detection device to an external electronic device.

According to the invention, the readout stack 40 is located vertically (along the Z axis) between the sensitive layer 12 of the visible matrix sensor 10 and the sensitive layer 22 of the infrared matrix sensor 20. In addition, it is connected by molecular bonding to the rear face of the visible matrix sensor 10.

The readout stack 40 thus includes an upper insulating layer 41, produced from an electrically insulating material, for example here from a silicon oxide. It forms a molecular bonding layer by which the readout stack 40 is connected by molecular bonding to the insulating layer 16 of the visible matrix sensor 10. The readout stack 40 includes electronic elements 42 covered by at least one main insulating layer 43 that has a planar lower face. This insulating layer 43 is produced from an electrically insulating material, for example here from a silicon oxide, and forms a molecular bonding layer for assembling the infrared matrix sensor 20 on the rear face.

Moreover, the interconnection stack 50 is a stack of the BEOL type (standing for Back End Of Line). It is formed by layers where metallisation levels are defined, which are separated vertically by inter-metal dielectric layers 55 (IMD, standing for Inter Metal Dielectric) and are connected together by conductive vias 54.

The interconnection levels are each formed by coplanar conductive portions 51, 52, 53, these being connected to those of the adjacent interconnection levels by conductive vias 54. The interconnection structure therefore includes several parallel interconnection levels arranged vertically above one another. It thus includes a first so-called upper interconnection level 51 located on the same side as the infrared sensor 20, intermediate interconnection levels 52, and a last so-called lower interconnection level 53 located on the same side as the support substrate 31.

The interconnection stack 50 is located under the infrared matrix sensor 20, here between the latter and the support substrate 31, and is therefore spaced apart from the readout stack 40 by the infrared matrix sensor 20. Moreover, as indicated previously, conductive vias 32, 34, 33 provide respectively an electrical connection, direct or indirect, between the electronic elements 14 of the visible matrix sensor 10, those 23 of the infrared matrix 20, and those 42 of the readout stack 40, and moreover the interconnection stack 50.

More precisely, at least one conductive via 34 provides an electrical connection, here direct, between the photodetector 23 of each infrared detection pixel and a conductive portion 51 of the upper metallisation level. Direct electrical connection means here that one and the same conductor extends between the two elements in question, here between the photodiode and the conductive portion. This conductive via 34 thus passes through the lower insulating layer 24, the reflective layer 63 (through an electrically insulated through opening in the layer 63) and the lower insulating layer 64.

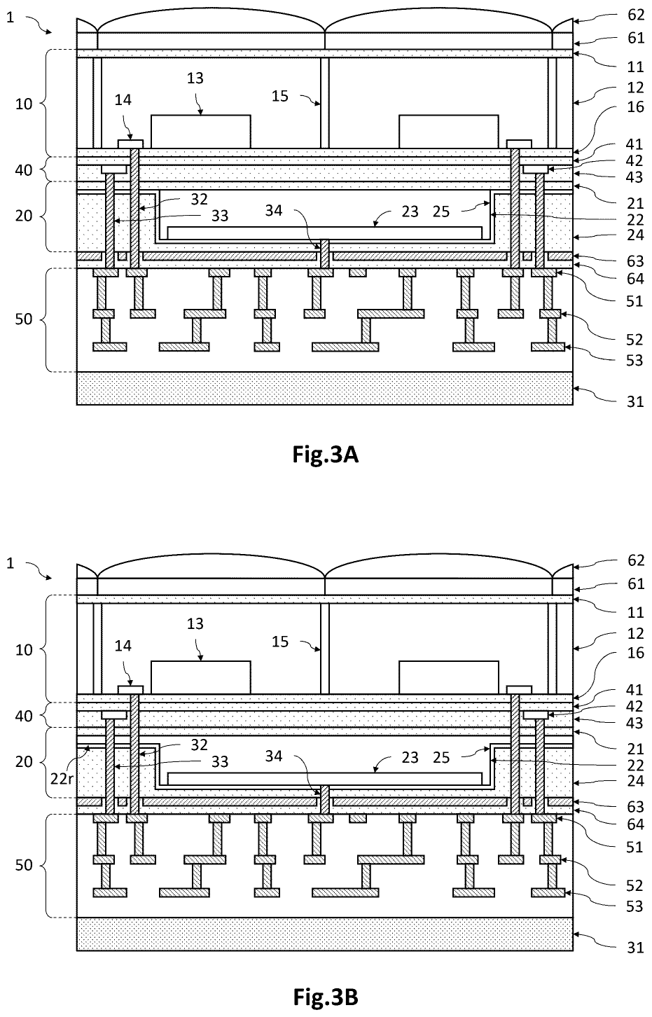

In addition, conductive vias 33 provide the electrical connection, here also direct, between the electronic elements 42 of the readout stack 40 and the conductive portions 51 of the upper metallisation level. These conductive vias 33 thus pass through the main insulating layer 43, the bonding insulating layer 21, the sensitive layer 22 in this example (but the sensitive layer 22 could be structured as described on FIG. 3B), the lower insulating layer 24, the reflective layer 63 (through an electrically insulated through opening in the layer 63) and the lower insulating layer 64. It should be noted that the conductive vias 33 pass through the sensitive layer 22 without electrical contact, since the conductive material of the vias 33 is surrounded by a sheath made from an electrically insulating material.

Finally, conductive vias 32 provide the electrical connection, here also direct, between the electronic elements 14 of the visible detection pixels and the conductive portions 51 of the upper metallisation level. These conductive vias 32 thus pass through the two bonding layers 16, 21, the main insulating layer 43, the bonding insulating layer 21, the sensitive layer 22 in this example, the lower insulating layer 24, the reflective layer 63 (through an electrically insulated through opening in the layer 63) and the lower insulating layer 64. It should also be noted that the conductive vias 32 pass through the sensitive layer 22 without electrical contact, since the conductive material of the vias 32 is surrounded by a sheath made from an electrically insulating material.

Thus the imaging device 1 has a structural configuration with four superimposed stages, which are formed successively from the visible matrix sensor 10, the readout stack 40, the infrared matrix sensor 20 and finally the interconnection stack 50 of the readout integrated circuit. This structural configuration is implemented by means of two molecular bonding steps, namely the bonding of the readout stack 40 on the rear face of the visible matrix sensor 10, and then the bonding of the infrared matrix sensor 20 on the rear face of the readout stack 40. Thus this makes it possible to reduce the integration and implementation constraints of the method, in particular in terms of thermal budget. This is because, by producing the readout stack 40 independently of and prior to that of the infrared matrix sensor 20, the thermal budget associated with the production of the electronic elements 42 (control transistors in particular) and in particular the high temperatures used (around 1000° C.) do not affect the quality of the sensitive layer 22 (for example made from Ge, SiGe, InGaAs, etc) of the infrared matrix sensor 20.

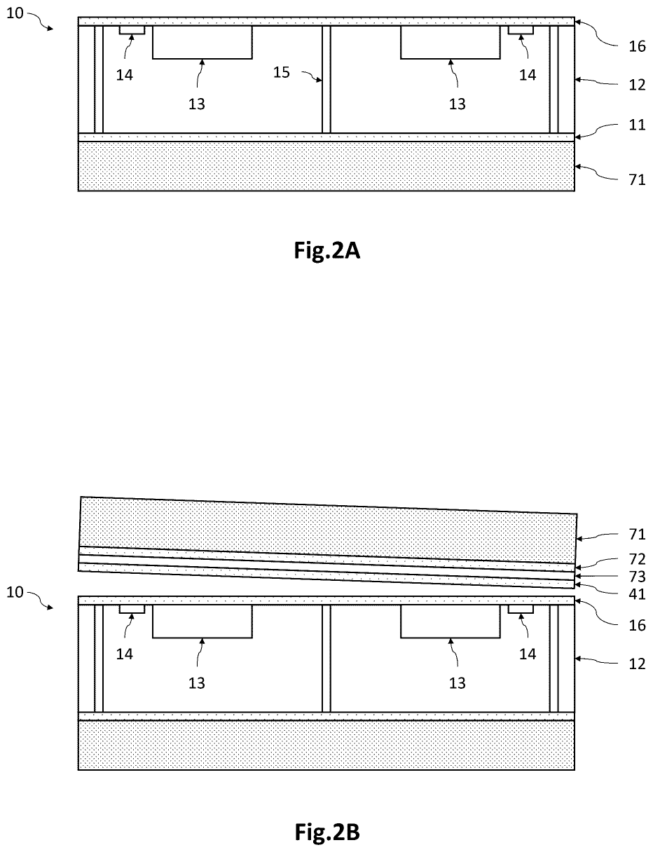

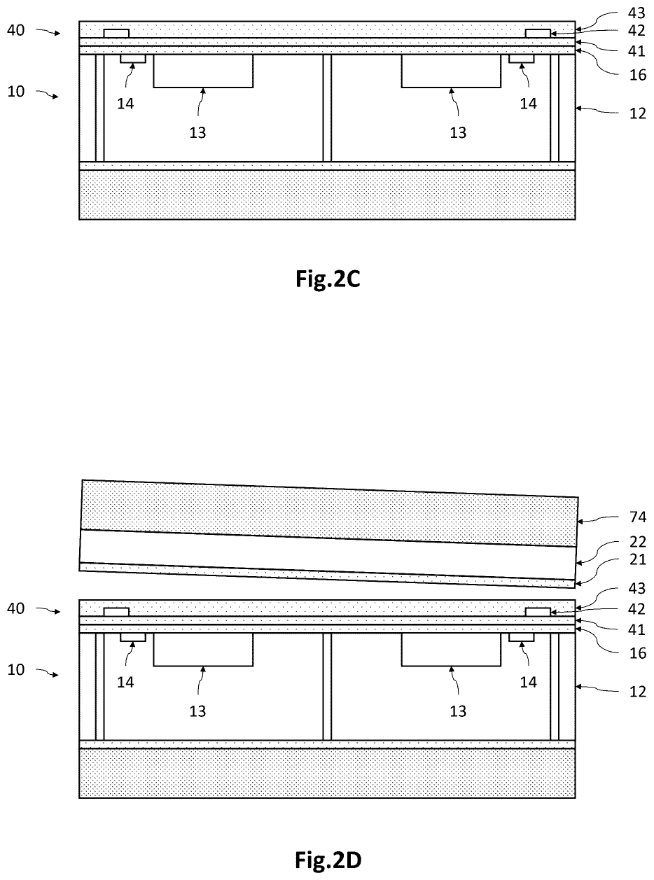

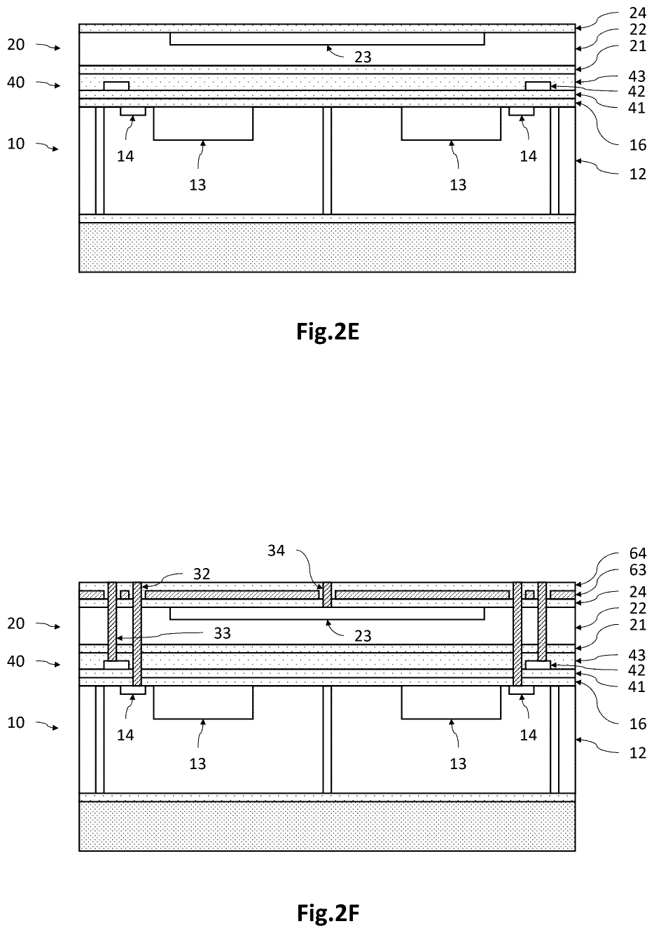

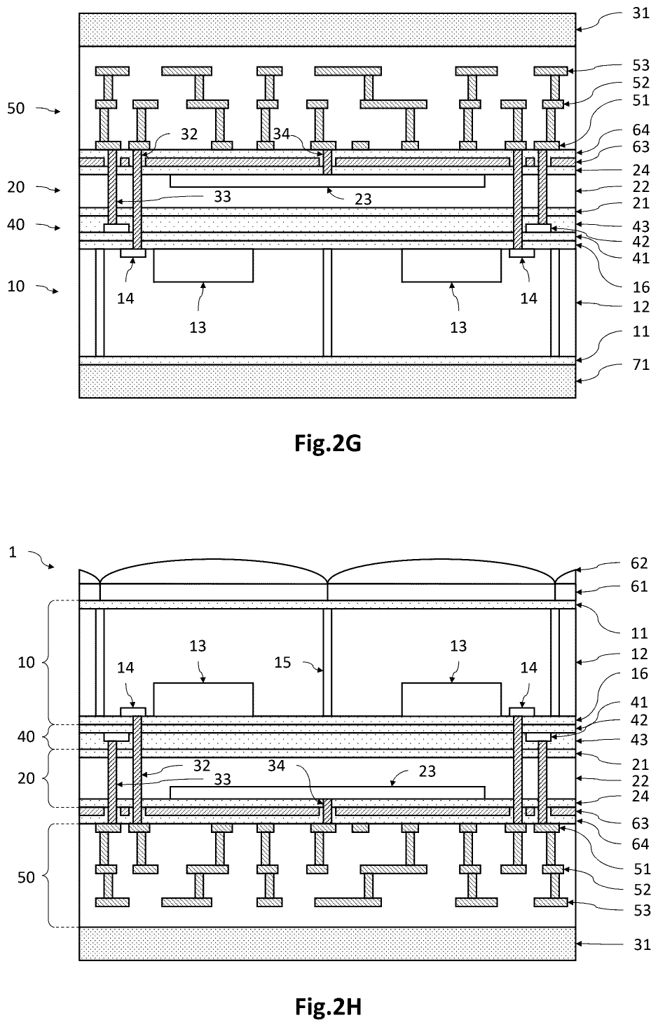

A method for manufacturing such an imaging device 1 is now described with reference to FIGS. 2A to 2H. In this example, the imaging device is identical to that of FIG. 1.

With reference to FIG. 2A, a structure is produced formed by a continuous layer (sensitive layer 12) made from monocrystalline silicon, resting on an oxide layer 11 and then on a handle layer 71 (here a thick silicon layer). The structure is produced from a first silicon on insulator (SOI) substrate. The isolation structures 15 are produced and, in the rear face of the sensitive layer 12, the photodiode 13 and the electronic elements 14 are produced by localised doping. The insulating layer 16, here made from a silicon oxide, is deposited so as to passivate the rear face of the sensitive layer 12 and to form a molecular bonding layer. This layer 16 may be a multilayer, formed for example from a sublayer providing the passivation and a sublayer providing the molecular bonding. This structure thus forms the visible matrix sensor 10.

With reference to FIG. 2B, an SOI substrate is produced formed from a thick support layer 71 of silicon, a buried oxide layer 72 and a thin layer 73 of monocrystalline silicon. The SOI substrate comprises an insulating bonding layer 41, produced from a silicon oxide, that covers the thin layer of silicon 73. It is assembled on the rear face of the visible matrix sensor 10, here by oxide/oxide molecular bonding, by putting the bonding layers 41, 16 in mutual contact.

With reference to FIG. 2C, the readout stack 40 is produced. For this purpose, the thick layer 71 is removed. Then the electronic elements 42 are produced using in particular the thin layers of silicon and oxide. Finally, the main insulating layer 43 is produced so as to cover the electronic elements and to have a planar rear face.

With reference to FIG. 2D, a structure is produced formed by a support layer 74, the sensitive layer 22, and an insulating layer 21, here made from silicon oxide, that provides the passivation of the sensitive layer 22 and the molecular bonding, here of the oxide/oxide type, with the main insulating layer 43. The insulating layer 21 may obviously be a multilayer, formed for example from a sublayer providing the passivation and a sublayer providing the molecular bonding. This structure is assembled on the rear face of the readout stack 40, here by oxide/oxide molecular bonding, by putting the insulating layer 21 in contact with the main insulating layer 43.

With reference to FIG. 2E, the infrared matrix sensor 20 is finalised. For this purpose, the thick layer 74 is removed so as to make free the rear face of the sensitive layer 22. Then the photodetectors 23 are produced, for example by localised doping, for example by ion implantations and by localised diffusions in the rear face. Finally, at least one passivation insulating layer 24 is deposited on the sensitive layer 22 so as to cover it continuously.

With reference to FIG. 2F, next the reflector 63 (advantageous) and then the interconnection stack 50 are produced. For this purpose, a reflective layer 63 is deposited so as to continuously cover the insulating layer 24. This reflective layer 63 is produced from a material adapted to reflect the incident radiation to be detected, for example a metal such as Ti, Al, Cu and alloys thereof, or even strongly doped silicon. The thickness of the reflective layer is adapted according to the material used, and may be of the order of 400 nm in the case of strongly doped silicon. The reflective layer 63 is next structured to form through openings intended for the conductive vias to pass. Then an insulating layer 64 is deposited so as to cover the reflective layer 63 and to have a preferentially planar rear face.

The conductive vias 32, 33, 34 are next produced, which are preferably produced from the same materials. Thus the conductive vias 32, 33, 34 extend here continuously, i.e. with continuity of the materials that constitute them, from the rear face of the lower insulating layer 64 is far as the photodiode 23 of the infrared detection pixel, as far as the electronic elements 42 of the readout stack 40, and as far as the electronic elements 14 of the visible detection pixels.

With reference to FIG. 2G, the interconnection stack 50 is next produced, commencing with the upper metallisation level 51, then the intermediate metallisation level 52, and finally the lower metallisation level 53. In particular, certain conductive portions 51 of the upper metallisation level are in contact with the conductive vias 32, 33, 34. Finally, a support substrate 31 is assembled on the interconnection stack 50. It should be noted that certain portions 51 of the upper metallisation level (on the periphery of the detection matrices) can be in electrical contact with the external connection pads that will be produced at the very end of the method.

With reference to FIG. 2H, the structure obtained is next returned to, and the handle layer 71 is removed so as to make free a face of the upper insulating layer 11. The colour filters 61 and the microlenses 62 are next produced. In this way an imaging device 1 is obtained the structural configuration of which has four stages: the visible matrix sensor 10, the readout stack 40 (assembled by molecular bonding to the visible matrix sensor 10), the infrared matrix sensor 20 (assembled by molecular bonding to the readout stack 40), and the interconnection stack 50. As indicated previously, this manufacturing method makes it possible to produce efficient electronic elements of the readout stack 40, by implementing in particular steps at high temperatures (around 1000° C.), without this being able to degrade the photodiode 23 of the infrared detection pixels.

External connection pads can also be produced.

FIG. 3A is a schematic partial view, in cross section, of an imaging device 1 according to a variant embodiment. In this example, the imaging device 1 is distinguished from the one in FIG. 1 essentially in that the sensitive layer 22 of the infrared matrix sensor 20 is not a continuous layer in the plane XY and common to all the detection pixels, but is formed by a plurality of sensitive-layer portions, distinct from one another in the plane XY. One and the same sensitive-layer portion 22 can extend facing a single visible detection pixel or, as here, facing a plurality of adjacent pixels. In this example, a passivation layer 25, produced from an electrically insulating material, covers the flanks and the rear face of the sensitive layer 22. This passivation layer 25 is optional. The conductive vias 32, 33 (which connect the electronic elements 14 of the visible detection pixels and those 42 of the readout stack 40) do not therefore pass through the sensitive layer 22 of the infrared detection pixels.

FIG. 3B is a schematic partial view, in cross section, of an imaging device 1 according to a variant embodiment similar to the one in FIG. 3A. In this example, the imaging device 1 is distinguished from the one in FIG. 3A essentially in that the adjacent sensitive-layer portions 22 are connected together in pairs by connecting portions 22r of lesser thickness, which correspond to not totally etched portions of the initial sensitive layer 22 presented on FIG. 2D. These connecting portions 22r are located in the same side as the upper insulating layer 21. The conductive vias 32 and 34 pass through these connecting portions 22r. This configuration is generally referred to as “shallow MESA”.

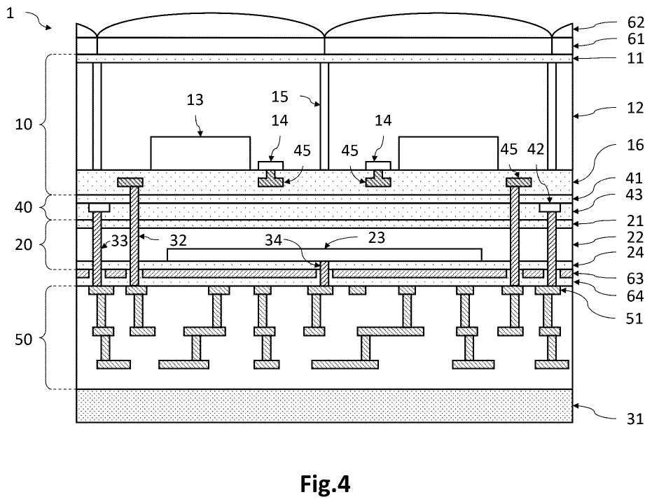

FIG. 4 is a schematic partial view, in cross section, of an imaging device 1 according to another variant embodiment. In this example, the imaging device 1 is distinguished from the one in FIG. 1 essentially in that electronic elements 14 of the visible detection pixels are not directly connected to the interconnection stack 50, each by one and the same conductive fear. This is because the readout stack 40 includes at least one electrical routing level formed by conductive portions 45.

More precisely, conductive portions 45 are located within the lower insulating layer 16 and extend in a planar manner. Certain zones of these conductive portions 45 are in electrical contact with the electronic elements 14 of the visible detection pixels, and other zones are in electrical contact with the conductive vias 32. There is therefore an indirect electrical connection between the electronic elements 14 and the interconnection stack 50, via the conductive portions 45. Here a single routing level (formed by the conductive portions 45) is shown, but several routing levels are obviously possible. These conductive portions 45 can be produced before the bonding step illustrated on FIG. 2B, for example based on doped silicon.

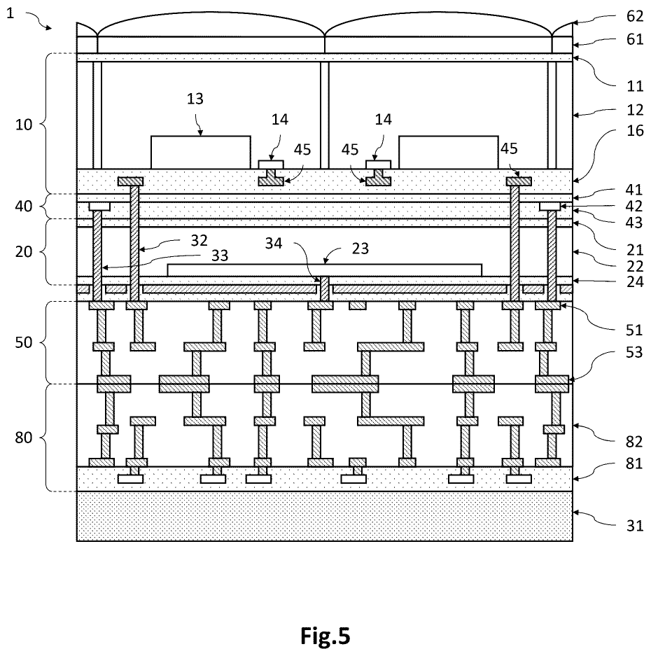

FIG. 5 is a schematic partial view, in cross section, of an imaging device 1 according to another variant embodiment. In this example, the imaging device 1 is distinguished from the one in FIG. 1 essentially in that it includes an additional readout substrate 80, assembled on the interconnection stack 50 on the rear face and electrically connected thereto. Thus the readout substrate 80 includes an interconnection stack 82, assembled by molecular bonding, for example a copper/oxide hybrid molecular bonding, to the interconnection stack 50, and a readout stack 81. Thus the imaging device 1 includes here two readout integrated circuits, one 40, 50 the readout stack 40 of which is located between the visible matrix sensor 10 and the infrared matrix sensor 20 and the interconnection stack 50 of which is located on the rear face of the infrared matrix sensor 20, and the other 80, which is assembled on the interconnection stack 50. This enables the imaging device 1 to distribute the electronic control functions of the visible 10 and infrared 20 matrix sensors on the two readout integrated circuits 40, 50, 80.

Particular embodiments have just been described. Various variants and modifications will become apparent to a person skilled in the art.

1. An imaging device, configured to acquire a visible image and an infrared image, including comprising:
a visible matrix sensor, including a first sensitive layer in which visible detection pixels including at least one electronic element are defined;
an infrared matrix sensor, including a second sensitive layer, superimposed on the first sensitive layer, in which infrared detection pixels including at least one electronic element are defined;
a readout integrated circuit, superimposed on the visible matrix sensor and on the infrared matrix sensor, formed by a readout stack including electronic elements and an interconnection stack;
wherein the readout stack is located between the first sensitive layer and the second sensitive layer, and in that the interconnection stack is located on the rear face of the infrared matrix sensor; and
wherein conductive vias electrically connect respectively the interconnection stack to the electronic elements of the visible matrix sensor, to the electronic elements of the readout stack, and to the electronic elements of the infrared matrix sensor.

2. The imaging device according to claim 1, wherein the visible matrix sensor includes a first insulating layer located under the first sensitive layer, and wherein the readout stack includes a second insulating layer located above the electronic elements of the readout stack, the first insulating layer and the second insulating layer being in contact with each other.

3. The imaging device according to claim 1, wherein the readout stack includes a third insulating layer located under the electronic elements of the readout stack, and wherein the infrared matrix sensor includes a fourth insulating layer located above the second sensitive layer, the third insulating layer and the fourth insulating layer being in contact with each other.

4. The imaging device according to claim 1, wherein conductive vias extend directly from the electronic elements of the infrared matrix sensor to conductive portions of the interconnection stack.

5. The imaging device according to claim 1, wherein conductive vias extend directly from the electronic elements of the readout stack to conductive portions of the interconnection stack.

6. The imaging device according to claim 1, wherein conductive vias extend directly from the electronic elements of the visible matrix sensor to conductive portions of the interconnection stack.

7. The imaging device according to claim 1, wherein conductive vias extend directly from conductive portions of the readout stack, which are in electrical contact with the electronic elements of the visible matrix sensor, to conductive portions of the interconnection stack.

8. The imaging device according to claim 1, wherein the second sensitive layer is a structured layer in a plane parallel to the plane of the infrared matrix sensor forming a plurality of portions of second sensitive layer, distinct from each other in the parallel plane, so that the conductive vias electrically connecting, respectively, the interconnection stack firstly to the electronic elements of the visible matrix sensor and secondly to the electronic elements of the readout stack, do not pass through the second sensitive layer.

9. The imaging device according to claim 1, wherein the second sensitive layer is a structured layer in a plane parallel to the plane of the infrared matrix sensor forming a plurality of portions of second sensitive layer, connected in pairs by a connecting portion of lesser thickness, so that the conductive vias electrically connecting respectively the interconnection stack firstly to the electronic elements of the visible matrix sensor and secondly to the electronic elements of the readout stack, pass through the connecting portions.

10. The imaging device according to claim 1, wherein the readout stack and the interconnection stack are first readout and interconnection stacks of a first readout integrated circuit, and wherein a second readout integrated circuit, formed by second readout and interconnection stacks, is assembled on the first readout integrated circuit the second interconnection stack being assembled and connected to the rear face of the first interconnection stack.

11. The imaging device according to claim 1, comprising a reflective layer, located between the infrared matrix sensor and the interconnection stack, adapted to reflect incident infrared radiation intended to be detected by the infrared matrix sensor.

12. The imaging device according to claim 11, wherein the reflective layer forms, with the infrared matrix sensor, the readout stack and an insulating layer located between the first sensitive layer and the readout stack, an optical cavity resonant at the wavelength of the infrared radiation.

13. A method for manufacturing an imaging device according to claim 1, comprising the following steps:
producing a visible matrix sensor, a first insulating layer covering the first sensitive layer where the electronic elements lie flush;
producing a first structure intended to form the readout stack, including a second insulating layer, by molecular bonding of the second insulating layer on the first insulating layer, and then producing the readout stack;
producing a second structure intended to form the infrared matrix sensor, including a fourth insulating layer, by molecular bonding of the fourth insulating layer on a third insulating layer of the readout stack, and then producing the infrared matrix sensor;
producing the interconnection stack as from the rear face of the infrared matrix sensor.

14. A manufacturing method according to claim 13, wherein, during the step of producing the electronic elements of the readout stack, a temperature rise to a temperature of at least 1000° C. is implemented.

15. The manufacturing method according to claim 13, wherein the step of producing the electronic elements of the infrared matrix sensor is implemented after the step of producing the electronic elements of the readout stack.
